(19) United States
(12) Patent Application Publication
(10) Pub. No.: US 2002/0001866 A1
(43) Pub. Date: Jan. 3, 2002

(54) Processing method of a plurality of films

(75) Inventors: Eiji Kido, Toyonaka-Shi (JP); Haruo Murano, Sakai-Shi (JP); Hiroshi Sakamoto, Shijonawate-Shi (JP); Masayuki Hisano, Katano-Shi (JP)

Correspondence Address: SIDLEY AUSTIN BROWN & WOOD, 717 NORTH HARWOOD, SUITE 3400, DALLAS, TX, 75201, US

(73) Assignee: MINOLTA CO.

(21) Appl. No.: 09/892,101

(22) Filed: Jun. 26, 2001

(30) Foreign Application Priority Data
Jun. 30, 2000 (JP) 2000-198220

(51) Int. Cl. H01L 21/00

(52) U.S. Cl. 438/30

(57) ABSTRACT

Disclosed is a processing method of a plurality of films that are used as substrates for liquid crystal display element(s). In the present processing method, each film is set to a film holder that has frame like shape and holds the film at its periphery. The film holders with the films are sequentially processed in a sequential process. On the other hand, the film holders with the films are set in a magazine cassette, and then the magazine cassette is simultaneously processed in a batch process.

### BACKGROUND OF THE INVENTION

1. FIELD OF THE INVENTION

The present invention relates to a method for processing a plurality of thin resin films, in particular to resin films which are utilized as substrates for liquid crystal display elements. In addition, the present invention relates to a process for a plurality of liquid crystal display elements.

2. DESCRIPTION OF THE RELATED ART

Conventionally, a variety of types of liquid crystal display elements have been developed and supplied and, in particular, liquid crystal display elements wherein a liquid crystal material showing a cholesteric phase and spacers or a resin structure, if necessary, hold between a pair of resin films have been developed.

In order to produce these types of liquid crystal display elements, films of the thickness of approximately 200 μm must be handled in a plural number of steps and it is extremely complicated to handle flexible films lacking resistance.

In view of the above described points, in Japanese unexamined patent publication H6(1994)-138427 a washing cassette which houses films in a bent condition so as to be held by utilizing the elasticity of the film is proposed. This cassette, however, has the following problem. That is to say, since the films are directly housed in the cassette so as to be washed, the flexible films must be directly handled after washing and this complication has not yet been overcome. In addition, since the films are simply put into grooves by bending, the films cannot be prevented from coming out of the cassette during washing or during transport.

### SUMMARY OF THE INVENTION

Therefore, the primary purpose of the present invention is to provide a method for processing films that avoids the above complication.

In addition, another purpose of the present invention is to provide a method for processing films which is suitable for batch processing and for sequential processing of a plurality of films.

Still another purpose of the present invention is to provide a process for a liquid crystal display element wherein a variety of types of processing of films is made efficient.

To accomplish at least one of the above mentioned objects, a processing method of a plurality of film that reflects one aspect of the present invention comprises the steps of:

holding a periphery of each of the films by a film holder;

executing a first process on the films that have been held by the film holders; and

executing a second process on the films that have been held by the film holders, the second process being different from the first process.

In the above mentioned processing method, these films may be sequentially processed in at least one of the first and second processes. In this specification, any processes in which the films are sequentially processed may be referred as a sequential process.

On the other hand, in the above mentioned processing method, these films may be simultaneously processed in at least one of the first and second processes. In this specification, any processes in which the films are simultaneously processed may be referred as a batch process. In this case, the film holders are preferably held in a magazine cassette, and the films are preferably processed in this state.

According to another aspect of the present invention, a processing method of a plurality of film comprises the steps of:

holding a periphery of each of the films by a film holders, respectively;

carrying out a sequential process on the films held by the film holders; and

carrying out a batch process on the films held by the film holders that have been installed in a magazine cassette.

In this processing method, the sequential process and the batch process may be carried out in any order. In a case where the batch process is carried out prior to the sequential process, the film holders are firstly set in the magazine cassette and then the batch process is carried out. After this, the film holders are drawn from the magazine cassette, and then the sequential process is carried out. On the other hand, in a case where the sequential process is carried out prior to the batch process, the sequential process is carried out on the film holders sequentially. After this, the film holders are installed or set to the magazine cassette, and then the batch process is carried out on these film holder.

According to these methods for processing, in the case that the films as the objects of processing are the films utilized as substrates for a liquid crystal display element, it is preferable for batch processing to be applied to, at least, one of film washing, drying, resist pre-baking, resist development, electrode film etching, resist exfoliation, insulating film burning, orientation film burning, spacer heat processing, seal burning and resin structure burning. In addition, it is preferable for sequential processing to be applied to, at least, one of film washing, drying, resist application, exposure to light, resist development, electrode film etching, resist exfoliation, insulating film application, insulating film burning, orientation film application, orientation film burning, spacer dispersion, seal printing and resin structure printing.

In any processing methods mentioned above, each film holder preferably has a shape suitable for exposing a major portion of the surface of the film. For example, each film holder may have a frame shape and holds a periphery of the film. To hold the film at its periphery, holding mechanism such as a clip, a magnet, a binder, and so on may be provided each frame shaped film holder.

### BRIEF DESCRIPTION OF DRAWINGS

These and other objects, advantages and features of the invention will become apparent from the following description thereof taken in conjunction with the accompanying drawings in which:

FIG. 1 is a front view showing the first example of a film holder;

FIG. 2 is a plan view of a sliding member of the film holder shown in FIG. 1;

FIGS. 3 to 5 are views showing a variety of modified examples of a holding mechanism;

FIGS. 6 to 9 are views showing a variety of modified examples of a sliding member;

FIG. 10 is a front view showing the second example of a film holder;

FIG. 11 is a perspective view showing a cassette which forms a film housing jig;

FIG. 12 is a plan view showing the condition where a film holder is housed in the above described cassette;

FIG. 13 is a cross section view showing one example of a liquid crystal display element gained through the process according to the present invention; and

FIG. 14 is a flow chart showing one example of the process according to the present invention.

### PREFERRED EMBODIMENTS OF THE PRESENT INVENTION

In the following, each of the embodiments of a method for processing films and a process for a liquid crystal display element according to the present invention are described.

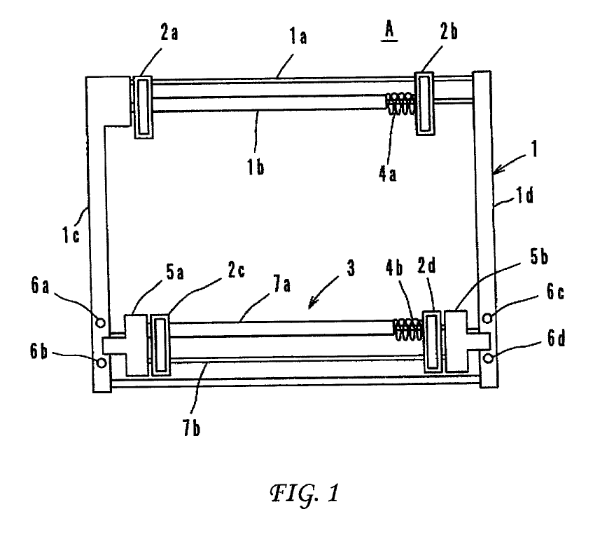

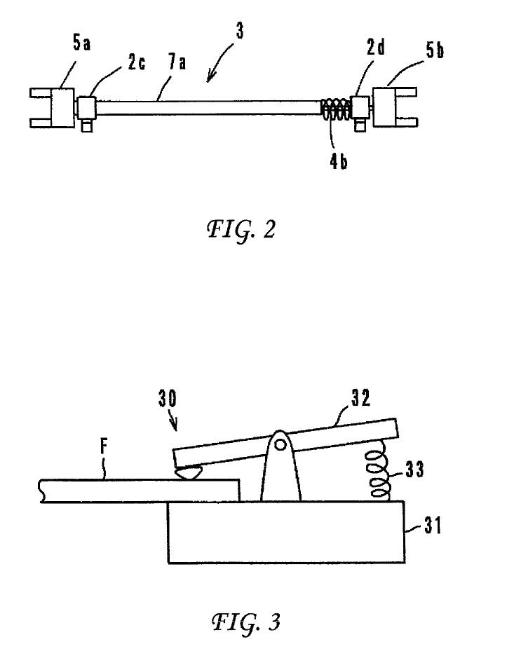

First Example of a Film Holder in Reference to FIGS. 1 and 2

FIG. 1 shows a film holder A onto which one film is mounted. Sequential processing can be carried out in the condition where a film is mounted onto this film holder A. This film holder A comprises a frame 1, of an approximate rectangular shape, holding mechanisms (clips) 2a to 2d and a sliding member 3. Though stainless steel may be used for the parts which form the above, in order to prevent metal dust from being created and, in addition, in order to prevent deterioration caused by acid, fluorine resin or plastics may also be used, or fluorine resin may be used to coat the surface of the stainless steel.

In the upper side of the frame 1, two rods, 1a and 1b, pass through alligator clips, 2a and 2b, which are the holding mechanisms. The clip 2a is fixed on the rods 1a and 1b while the clip 2b is made to be smoothly removable in the lateral direction without being fixed on the rods 1a and 1b. The right end part of the rod 1b becomes narrower so that the left end of a coil spring 4a is held at the place where the thickness of the rod changes and the rod presses the spring 4a in the direction toward the clip 2b in an elastic manner.

A film is held on the upper end part by being clasped in two places, on the left and on the right, with clips 2a and 2b, respectively. At this time, the clip 2b clasps the film while appropriately pressing the spring 4a. Accordingly, when the external force is removed after the film has been clasped, the spring 4a presses the clip 2b in the right direction so as to recover its original form and, thereby, an appropriate tension is applied to the film in the lateral direction.

The slide member 3 provided on the lower side of the frame 1 is shown in FIG. 2 in the condition as viewed from above. The slide member 3 is not fixed to the frame 1. Dislocation prevention members 5a and 5b are, respectively, fixed to both the left and right ends of the slide member 3. The parts of the dislocation prevention members 5a and 5b that make contact with the vertical members 1c and 1d of the frame 1 are U-shaped so as to engage, in a movable condition, the vertical members 1c and 1d with appropriate gaps maintained in between. Protruding parts 6a to 6d are provided in the vicinity of the locations where the vertical members 1c and 1d make contact with the dislocation prevention members 5a and 5b so that even in the case where an unexpectedly large amount of external force is applied to the slide member 3, the U-shaped parts of the dislocation prevention members 5a and 5b contact at least one of the protruding parts 6a to 6d so as to prevent the slide member 3 from coming out of the frame 1.

In the slide member 3, the dislocation prevention members 5a and 5b are linked with the rods 7a and 7b which are placed there between. The rods 7a and 7b pass through the clips 2c and 2d. The clip 2c is fixed on the rods 7a and 7b while the clip 2d is made to be smoothly moveable in the lateral direction without being fixed onto the rods 7a and 7b. The right end part of the rod 7a becomes narrower so that the left end of a coil spring 4b is held at the place where the thickness of the rod changes and the rod presses the spring 4b in the direction toward the clip 2d in an elastic manner.

The film is held by being clasped in two places, on the left and on the right, with clips 2c and 2d, respectively. At this time, the clip 2d clasps the film while appropriately pressing the spring 4b. Accordingly, when the external force is removed after the film has been clasped, the spring 4b presses the clip 2d in the right direction so as to recover its original form and, thereby, an appropriate tension is applied to the film in the lateral direction.

That is to say, the adjustment of the tension in the horizontal direction is carried out primarily by the springs 4a and 4b.

As described above, the four places of the film are, respectively, clasped by the clips 2a to 2d and the film holder A is stood up and then tension in the vertical direction is applied to the film due to the gravity affecting the slide member 3. That is to say, the adjustment of the tension in the vertical direction is carried out primarily by the slide member 3.

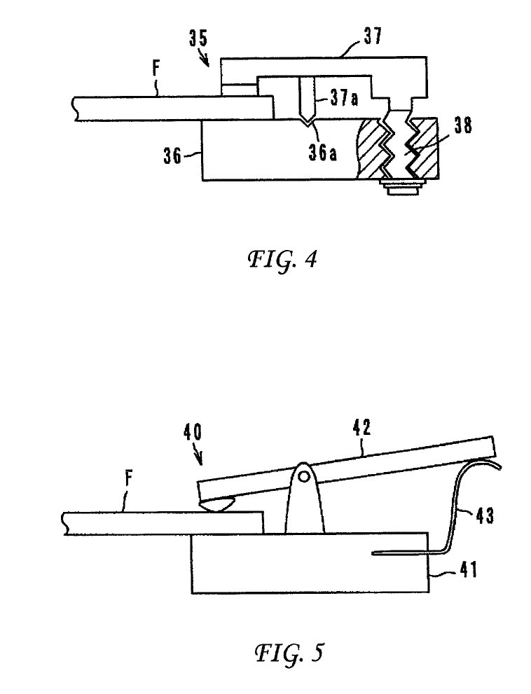

Another Example of Film Holding with Reference to FIGS. 3 to 5

Here, in the hold on the film, a clasping force which is sufficiently strong enough to prevent the dislocation of the film during the operation can be applied and a variety of clasping configurations can be used. For example, the above described alligator clips or clips of an approximate U-shape can be utilized and pins which clasp by means of magnetic power may be used. In addition, flexible members, such as a silicon tube, may be attached to the parts where the holding mechanisms make contact with the film so that the film can be prevented from being damaged.

FIG. 3 shows a holding mechanism 30 which clasps the film F wherein a holding member 32 is pressed to a stationary member 31 with a compression coil spring 33.

FIG. 4 shows a holding mechanism 35, wherein a holding member 37 is attached to a stationary member 36 with a screw 38 so as to be rotatable, that clasps the film F when the holding member 37 is rotated to a predetermined position. A recess 36a which is formed in the stationary member 36 and a protruding part 37a which is provided on the holding member 37 determine the clasping position. Here, the holding member 37 may be a plate spring while the screw 38 may be, merely, the axis member.

FIG. 5 shows a holding mechanism 40 wherein a holding member 42 is pressed against the stationary member 41 with a plate spring 43 in an elastic manner so as to clasp the film F.

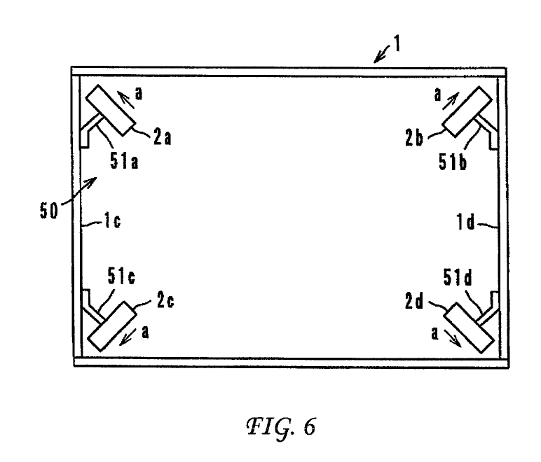

Another Example of the Tension Adjustment Mechanism in Reference to FIGS. 6 to 9

In addition, as a tension adjustment mechanism a variety of modifications other than the adjustment mechanism (springs 4a and 4b, slide member 3, and the like) shown in FIG. 2 are possible and are described by citing examples as follows.

FIG. 6 shows a tension adjustment mechanism 50 wherein clips 2a to 2d are attached to longitudinal members 1c and 1d of a frame 1 via plate springs 51a to 51d. The plate springs 51a to 51d press the clips 2a to 2d in the directions toward the four corners, respectively, of the frame 1 (directions of the arrows a in the figure) in an elastic manner. The clips 2a to 2d clasp the film while being pressed in the opposite directions to the arrows a and, then, the external force is removed so that the plate springs 51a to 51d attempt to recover their original form thereby applying tension to the film.

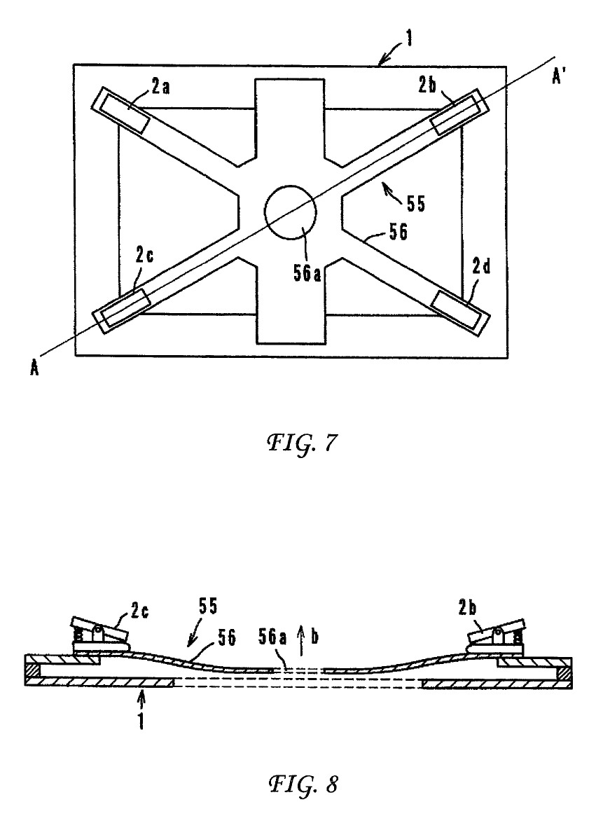

FIGS. 7 and 8 show a tension adjustment mechanism 55 wherein a plate spring 56 is attached to the frame 1 so as to extend along the diagonal lines thereof and wherein clips 2a to 2d are provided at the edges of the plate spring 56. A hole 56a is created in the center of the plate spring 56, which creates an elastic pressure in the direction of the arrow b in FIG. 8. The clips 2a to 2d clasp the film while pressing the plate spring 56 in the direction opposite to this arrow b and, then, the external force is removed so that the plate spring 56 attempts to recover its original form, thereby applying tension to the film.

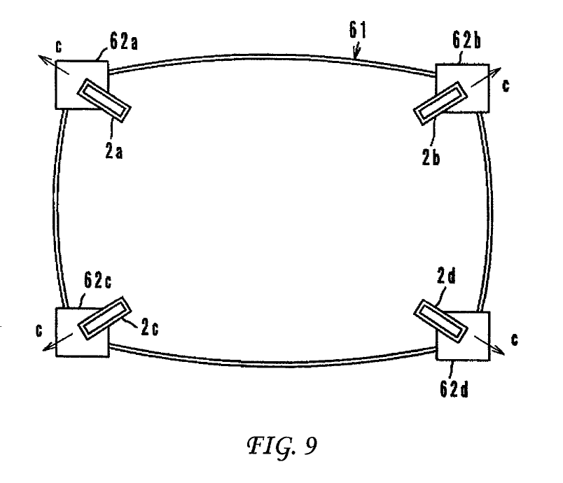

FIG. 9 shows a tension adjustment mechanism created by the frame 61, itself This frame 61, made of an elastic member, presses clips 2a to 2d, provided in the four corners via mounts 62a to 62d, in the directions of the arrows C. While pressing the four corners of the frame 61 in the directions opposite to the arrows c, the film is clasped by the clips 2a to 2d and the external is removed so that the frame 61 attempts to recover its original form, thereby applying tension to the film.

In each of the examples shown in FIGS. 6 to 9, as a result of the application of an appropriate tension in the directions toward the four corners of the film (that is to say, in the directions diagonal to the film), an appropriate tension is applied in the horizontal direction and in the vertical direction of film. In addition, a slide member such as the slide member 3 of FIG. 1 becomes unnecessary and, therefore, the configuration of the film holder becomes simpler and the occurrence of problems, such as the creation of dust, is reduced.

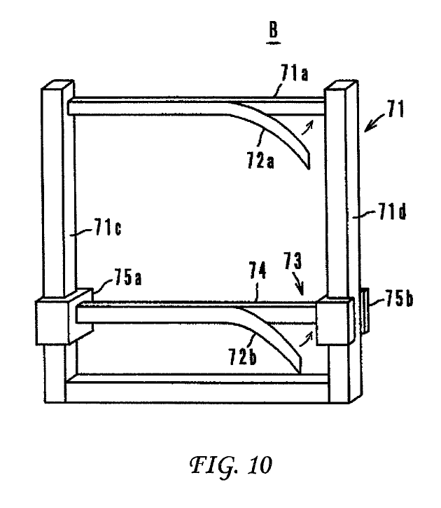

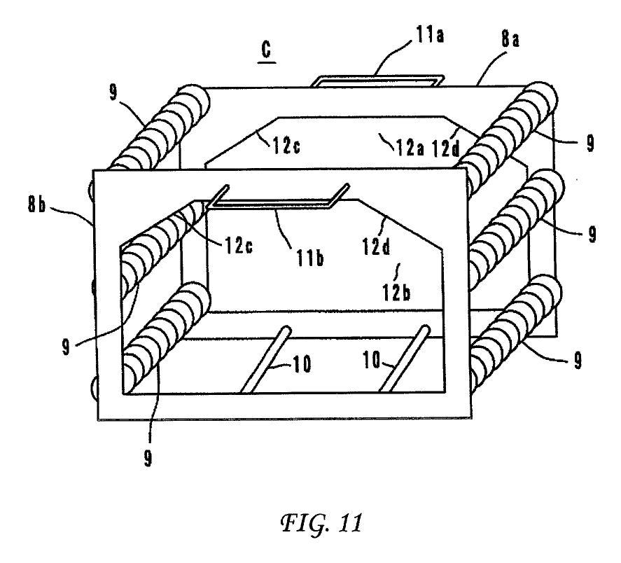

Second Example of Film Holder in Reference to FIG. 10

FIG. 10 shows another film holder B. This film holder B comprises a frame 71 of an approximate rectangular shape, holding mechanisms (flexible magnetic plates) 72a and 72b and a slide member 73. The upper side of the frame 71 is formed of a metal plate 71a and the band-shaped magnetic plate 72a is attached to this metal plate 71a so as to hold the upper end part of the film in between.

Dislocation prevention members 75a and 75b, which are of a U-shape, are fixed on both ends of the slide plate 74, made of metal, of the slide member 73. The dislocation prevention members 75a and 75b are engaged with the longitudinal members 71c and 71d of the frame 71 in a movable manner so as to be able to move freely in the upward and downward directions along the longitudinal members 71c and 71d. The lower end part of the film is held between the slide plate 74, made of metal, and the band-shaped magnetic plate 72b, by attaching the magnetic plate to the slide plate. The frame 71 is stood up in this condition and, then, an appropriate tension is applied to the film in the vertical direction due to the gravity affecting the slide member 73. In addition, the film is pressed by the magnetic plates 72a and 72b in the lateral direction so as to be prevented from being altered in form.

The utilization of the band-shaped magnetic plates 72a and 72b as holding means allows the entire part of the upper and lower ends of the film to be able to be held without damage to the film and, therefore, is preferable. Here, the magnets may be in a strap form or magnets of other shapes may be utilized.

In the above described second example, though the slide member 73 adjusts the tension in the vertical direction, no mechanisms are provided in order to apply tension in the horizontal direction. However, since the magnets 72a and 72b make a line contact or an area contact along the upper and lower ends of the film, expansion and contraction of the film can be dealt with to a certain extent by appropriately setting the attraction power of these magnets. Accordingly, expansion or contraction members, such as springs 4a and 4b shown in FIG. 1, become unnecessary so that the configuration of the film holder becomes simpler.

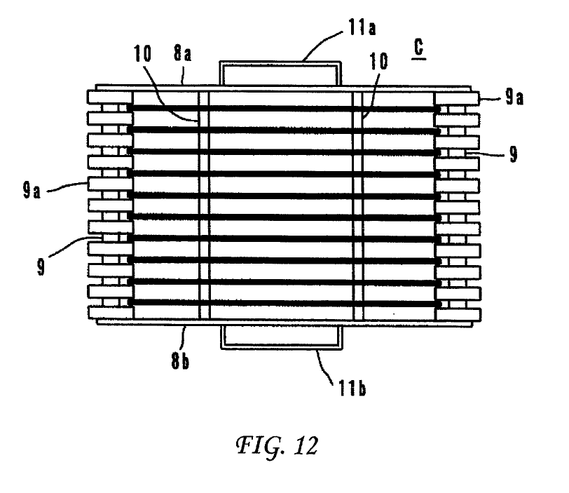

Example of Cassette in Reference to FIGS. 11 and 12

FIGS. 11 and 12 show a cassette C for housing a plurality of the above described film holders A or B, or film holders of other configurations. In the following, cassette C, as the housing of the film holders A, is described. The film holders A are inserted, in the downward direction, through the upper side opening of the cassette C so as to be set in the standing condition. A batch process is carried out in the condition where a plurality of holders A, each of which holds a film, are put into this cassette C.

This cassette C comprises two plane members 8a and 8b facing each other, guide rods 9, making a link between those plane members 8a and 8b using three rods thereof per side, two rods 10, making a link between those plane members 8a and 8b at the bottom, and handles 11a and 11b. Though each of the components may be made of stainless steel, in order to absorb the shock applied to the films, in order to prevent metal dust from being created or in order to prevent the deterioration caused by acid, they may be made of fluoride resin or other plastic, or the surface of the stainless steel may be coated with fluoride resin.

FIG. 12 shows the condition where ten film holders A, which hold films, are inserted into the cassette C. Flange parts 9a are provided at equally spaced intervals on the guide rods 9 corresponding to the number of housed film holders A so as to smoothly guide the insertion and removal, in the vertical direction, of the film holders A between the flange parts. In addition, the flange parts 9a maintain predetermined intervals between the housed holders A so as to prevent the adjacent films from making contact. Moreover, the lower sides of the film holders A are supported by the rods 10, 10.

Here, the flange parts 9a of the guide rods 9 may be formed in a smooth curved form and, in this case, the film holders A can be prevented from being caught at a flange part 9a at the time of insertion or removal and, at the same time, the advantage is gained that when the films are subjected to the washing process while held in the cassette C, water can be spun off quickly.

In addition, openings 12a, 12b are provided in the plane members 8a, 8b. The upper sides of the openings 12a, 12b are connected to the diagonal sides 12c and 12d on both sides so that the width of the openings in the horizontal direction becomes smaller as it approaches the upper sides. In the case that the cassette C is handled by an automated device, the arms, not shown, are hooked onto the upper sides of the openings 12a, 12b so that the cassette is lifted up or carried. Because of the formation of the diagonal sides 12c and 12d, only in the case that the arms are once placed within the openings 12a, 12b do the arms naturally settle in the part of which the width matches the width of the arms at the time when the cassette C is lifted up in the vertical direction, even without the precise positioning of the arms and the cassette C, by being hooked by the arms so that the cassette C can be stably held while being carried.

In addition, the cassette C can be carried by holding the handles 11a, 11b with the hands.

The film containing jig, which comprises the above described film holders and the cassette, is formed so that the films of which the thickness is 200 μm, or less, can be specifically handled. A thick film of which the thickness exceeds 200 μm has a sufficient elasticity and, therefore, the film can be held without coming out by a simple structure such that the both ends of the films facing each other are put into grooves provided on the two respective sides of the cassette. In the case that the thickness of the film is 200 μm, or less, however, the film has a weak elasticity and the structure wherein the films are held only by being put into the grooves allows the films to easily come out during a variety of process steps for producing a liquid crystal display element which are described in detail below. Therefore, the above described film containing jig firmly holds the films by using the film holders so that the plurality of film holders are housed in the cassette under this condition so as to allow batch processing. Here, at the time of individual processing, the film holders are removed from the cassette and the processing is carried out under the condition where the films are held in the film holders.

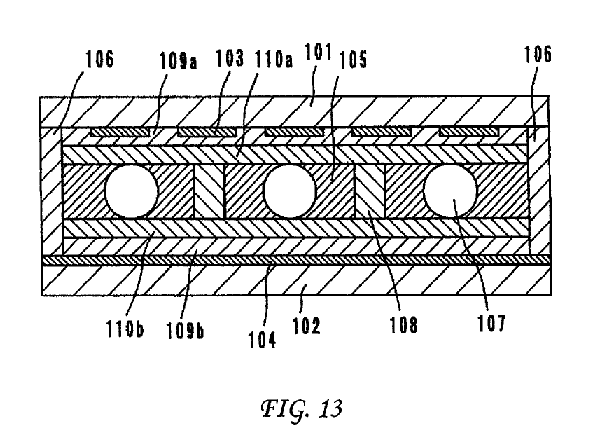

Example of a Liquid Crystal Display Element in Reference to FIG. 13

Liquid crystal display elements are produced by using the above described film containing jig, including film holders and cassette. FIG. 13 shows an example of a manufactured liquid crystal display element, which has a single layered liquid crystal layer. Here, liquid crystal layers which are placed and held between substrates can be layered in a plural number so as to manufacture a liquid crystal display element which makes, for example, a full color display possible.

In FIG. 13, two resin substrates which face each other and which are transparent are denoted as 101 and 102. As for the materials of such resin substrates 101, 102, polyether sulfon, polyethylen terephthalate, polycarbonate, or the like, for example, can be cited and a thin elastic film can be utilized.

Transparent electrodes 103, 104 are, respectively, arranged on the surfaces of the resin substrates 101, 102 so as to face each other. This liquid crystal cell has a simple matrix electrode structure wherein a plurality of band transparent electrodes 103, 104 face each other so as to cross each other at right angles. Here, though the below described electrode formation process is shown with respect to a simple matrix electrode, the present invention is not limited to this but, rather, can be applied to the case where an active matrix electrode structure is adopted. As for the material of the transparent electrode, in addition to indium tin oxide (ITO), metal electrodes such as indium zinc oxide (IZO), aluminum, silicon, or the like, for example, and photoconductive films such as amorphous silicon, bismuth silicon oxide (BSO), or the like, for example, can be used.

A liquid crystal layer 105 is placed and held between the two resin substrates 101 and 102. As for the liquid crystal materials typically used in the liquid crystal display element of the structure shown in FIG. 13, for example, polymer dispersion type liquid crystal, cholesteric nematic phase shift type liquid crystal, liquid crystal which selectively reflects light in the visible light wavelength range (cholesteric liquid crystal, chiral nematic liquid crystal wherein chiral material is added to nematic liquid crystal, or the like) can be cited. In the case of the latter, as for the substrate 2 on the opposite side of the viewed side, substrates which absorb light (a black substrate, a substrate coated in black, or the like) may be used.

Twisted nematic type liquid crystal, super twisted nematic type liquid crystal, ferroelectric liquid crystal or anti-ferroelectric liquid crystal which exhibits smectic phase at room temperature, or the like, can, of course, be used by providing members such as a polarized plate, a light reflecting layer and a color filter, in addition to the configuration of FIG. 13, if necessary.

Seal walls 106 for sealing liquid crystal are provided outside of the display region in the outer periphery part of the resin substrates 101, 102. As for the sealing material thermosetting resin, or the like, for example, can be used.

In order to maintain the liquid crystal layer 105 at a predetermined thickness, bead spacers 107 and resin structures 108 are arranged. Both of, or either one of, the bead spacers 107 and the resin structures 108 may be used. Bead spacers 107 may be mixed into the resin structures 108. As for the material of the bead spacers 107, inorganic materials, such as miniaturized glass fibers, silica glass in ball form or alumina powder, or organic synthesized particles of spherical shape such as divinylbenzene-based cross linking polymer or polystyrene-based cross linking polymer can be used. In addition, in the case that resin coated spacers are used, the spacers 107 can be fixed between the substrates through heat processing.

As for the resin structures 108, a variety of resin materials can be utilized and organic materials which do not cause chemical reactions with the utilized liquid crystal material and which have an appropriate elasticity are, preferably, utilized. As for examples of such materials, polyvinyl chloride resin, polyvinylidene chloride resin, polyvinyl acetate resin, polymethacrylic resin, poly-acrylic acid ester resin, polystyrene resin, polyamide resin, polyethylene resin, polyurethane resin, polypropylene resin, fluorine-based resin, polyacrylonitrile resin, polyvinyl ether resin, polyvinyl ketone resin, polyether resin, polycarbonate resin, chlorinated polyether resin, polyvinyl pyrolidone resin and saturated polyester resin are cited and a plurality of these may be combined for use.

Here, as for the resin structures 108, not only thermoplastic resin but also thermosetting resin, light setting resin, or the like, can be used.

In addition, insulating films 109a, 109b are provided, respectively, on the substrates 101, 102 in order to prevent the electrodes 103, 104 from forming a short circuit. As for the materials of the insulating films 109a, 109b, an inorganic film, such as of silicon oxide, or an organic film, such as of polyimide resin or epoxy resin, can be utilized.

In addition, orientation control films 110a, 110b may be, respectively, provided on the insulating films 109a, 109b for controlling the molecular arrangement direction of the liquid crystal. As for the material of such orientation control films 110a, 110b, polyimide resin, or the like, are representative.

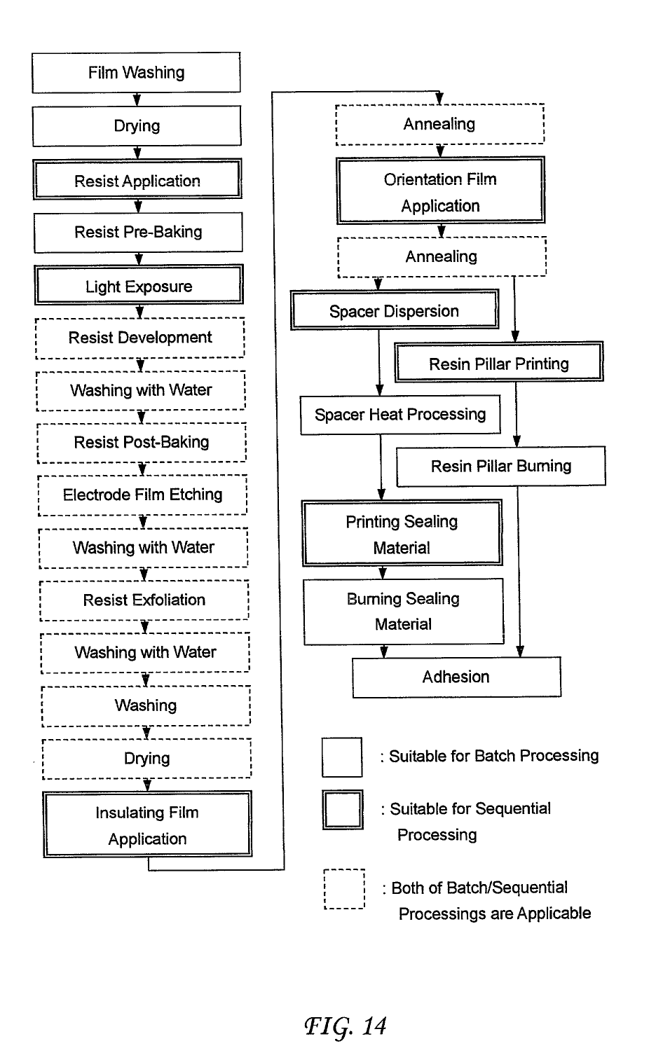

Process in Reference to FIG. 14

Next, a process for a liquid crystal display element using the above described film containing jig, including the film holders and the cassette, is described.

FIG. 14 is a flow chart showing an example of a process for a liquid crystal display element using film substrates.

First, film substrates are washed with a variety of washing liquids and water (film washing) and drying is carried out (drying). Then, in order to form a transparent conductive film which becomes an electrode, a photoresist material is applied (resist application), and the photoresist is burned (resist pre-baking) and, after that, light exposure is carried out through a mask (light exposure). In addition, the photoresist is developed by using the developer (resist development), the developer which has attached to the film is washed away (washing with water), and the remaining photoresist is, again, burned (resist post-baking). After that, the transparent conductive film is etched by using etching liquid (electrode film etching), washing with water is carried out (washing with water) and the photoresist is exfoliated with exfoliation liquid (resist exfoliation). Next, washing is carried out by using water and washing liquid (washing with water, washing), as well as is drying, to gain substrates with electrodes.

After that, insulating film material is applied on the electrode surfaces of the substrates through printing, or the like, (insulating film application), and is closely attached to the substrates through burning (annealing). In addition, an orientation control film material is applied on the insulating film through printing, or the like, (orientation film application), and is closely attached to the substrates through burning (annealing).

Next, spacers are dispersed on one of the substrates (spacer dispersion). In the case that resin coated spacers, or the like, are used, the spacers may be temporarily fixed on the substrate through heating (spacer heat processing) so as to facilitate the subsequent processing.

In addition, a sealing material is formed on said substrate through printing, or the like, (printing of sealing material), and burning is carried out to convert the sealing material into the half-set condition (burning of sealing material). The sealing material may, of course, be formed on the other substrate.

Structures, such as resin pillars made of thermoplastic resin material, or the like, arranged according to a predetermined regularity, are formed on the part of the other substrate which becomes a display region of the liquid crystal display element through printing, or the like, (resin pillar printing). Then, the resin structures are burnt by applying heat for the purpose of removing solvents, or the like, (resin pillar burning).

Then, both substrates are adhered to each other with sealing material so that the electrode surfaces thereof face each other (adhesion). In this case, a method (for example, a method described in U.S. Pat. No. 6,226,067) can be adopted wherein liquid crystal material is supplied between the substrates and heat and high pressure are applied while one of the substrates is being bent and, thereby, the substrates are adhered to each other while the liquid crystal material is sealed in.

All of the above described steps may, essentially, be carried out in a batch processing except for the steps which can be implemented only by an individual serial process. For example, the steps wherein substrates are immersed in a liquid for a predetermined period of time, such as washing, development or exfoliation of a resist or etching and heat treatment steps, such as drying, burning or other heat application processes, are suitable for batch processing. By carrying out batch processing, comprehensive processing can be carried out on a plurality of substrates as the object so that the efficiency of the processing can be enhanced. In addition, the process dispersion among a plurality of substrates can be restricted.

In particular, film washing, drying, resist pre-baking, resist development, electrode film etching or resist exfoliation, annealing Insulating film burning, orientation film burning), spacer heat processing, burning of sealing material and resin pillar burning are suitable for batch processing.

The washing step may be individually carried out in a serial manner in order to enhance the washing efficiency. In addition, the steps such as electrode film etching, development or exfoliation of a resist may be individually carried out in a serial manner in order to ensure the processing.

On the other hand, individual serial processing is essentially appropriate when being applied solely to the steps that can only be implemented by individual serial processing. By carrying out individual serial processing, effective processing can be carried out on each substrate without fail.

In particular, washing, resist application, light exposure, resist development, electrode film etching, resist exfoliation, insulating film application, orientation film application, spacer dispersion, printing of sealing material and resin pillar printing are suitable for individual serial processing.

Embodiment of Process

In the following, an embodiment of a process realized by the present inventors is described.

The utilized film holders are in an approximate frame form of which the width is 430 mm, the height is 360 mm, and the thickness is 5 mm. As for the material, stainless steel of which the surface is coated with a fluorine resin is used.

As for the cassettes, the width is 450 mm, the height is 370 mm and the depth is 250 mm. As for the material thereof, a fluorine resin is used for the film guides and stainless steel is used for the other members.

A process for a liquid crystal display element is carried out by using these film containing jigs.

A plurality of polycarbonate film substrates with ITO (made by Teijin Corporation, of a thickness of 100 μm) which are cut into the size with a width of 390 mm and a length of 300 mm are prepared and each of these is mounted in a film holder of FIG. 1. That is to say, by holding the peripheral part of each film with the holding mechanism of each film holder, the film substrate is mounted to the film holder. Ten film holders, in which films are mounted, are contained in the cassette of FIG. 11. Under this condition, the washing of the film substrates is carried out in a batch processing. The washing of the film substrates is carried out in an automated washing device comprising four tanks.

Next, the washed films are dried by being placed in an oven. The drying is also carried out by means of batch processing and the cassettes taken out of the washing device are put into the oven as they are. The drying is carried out for 20 minutes at a temperature of 80° C.

Next, the patterning of the ITO is carried out. As for the patterning of the ITO, band-shaped electrodes are gained through patterning using a photolithographic method, as described below.

First, an application of a resist to the film surface is carried out. The application of the resist is carried out in an individual serial processing. That is to say, a film holder is taken out of a cassette and the application is carried out by using a spin coat method in the condition where a film is mounted in the film holder.

Pre-baking is carried out on the applied resist. The pre-baking is carried out for 50 minutes at the temperature of 80° C. in an oven. The pre-baking is carried out in an individual serial processing in the condition where a film is mounted in the film holder.

Next, pattern exposure is carried out by means of individual serial processing and then the exposed pattern is developed. The development is carried out by means of individual serial processing. The developed film is washed with water by means of individual serial processing and is placed into a cassette so as to be post-baked by placing in the oven by means of batch processing. The post-baking is carried out for 20 minutes at 80° C. In addition, etching of ITO is carried out. A weak acid is used for an etching liquid and individual serial processing is carried out. After completing the etching, washing with water is again carried out by means of individual serial processing so that exfoliation of the still remaining resist is carried out. A solution with a 2% concentration of NaOH is used for the exfoliation of the resist which is carried out by means of individual serial processing.

Though these steps of development, etching, exfoliation and washing are carried out by means of individual serial processing, they can, of course, be carried out by means of batch processing by immersing the loaded cassettes in the developer, the etching liquid, or the like. In addition, by using a fluorine resin as the jig material or by using plastic clips or magnets as the holding mechanisms, deterioration of the jigs due to acid can be prevented.

Films which have undergone ITO patterning are, again, placed in the cassettes and are washed and dried by means of batch processing. The washing and drying are carried out in an automated washing device and in an oven in the same manner as were performed the first time.

Next, printing of an insulating film and an orientation control film is carried out. A film holder is again taken out of the cassette and the printing is carried out by means of individual serial processing by using a roll coat method. The insulating film annealing and the orientation control film annealing are both, respectively, carried out on a hot plate for 10 minutes at a temperature of 140° C.

Resin film-coated bead spacers are dispersed on one of the substrates. Spacer dispersion is carried out by means of individual serial processing and bead spacers with a diameter of 5 μm are dispersed. A screen printing method is used for the printing of the sealing material wherein a sealing material is printed on the peripheral part of the display part. Spacer heat processing and the burning of sealing material are carried out by means of batch processing wherein an oven is used and film holders are mounted in the cassettes.

Resin structures are printed on the other substrate. The resin structure printing is carried out by means of individual serial processing by using a screen printing method. The burning of the resin structures is carried out by means of batch processing by using an oven and by putting the film holders back into the cassettes.

Two substrates formed in the above described manner are adhered to each other while sealing in a liquid crystal material there between. An appropriate amount of the liquid crystal material is dropped onto one of the substrates by using a dispenser and the substrate is made to face the other substrate so as to adhere together while heat and high pressure are applied. Heat application and high pressure application are carried out by using a roller. Adhesion is carried out after removing the films from the film holders.

A driving circuit is connected to the completed liquid crystal display element.

In the above described process for a liquid crystal display element, since films are mounted in the film holders, large and thin films can be easily handled by means of individual serial processing while batch processing can be carried out efficiently. The insertion and removal of the film holders into the cassettes is smooth so that the switching between individual serial processing and batch processing can be easily carried out. In addition, no films come out of the film holders and no films make contact with adjacent films during film washing, drying or burning. At the time when a cassette is lifted up with the arms for washing, the arms settle naturally on the upper end part of the openings of the cassette sides so that the cassette is stable while being carried. Thus, the manufactured liquid crystal display elements have no scratches or cracks in substrates or on the ITO so as to have a very high display quality.

Other Modes

Here, process methods or manufacturing methods according to the present invention are not limited to the above described mode but, rather, can be modified in a variety of manners within the scope of the gist of the invention.

In particular, the detailed structures of the film holders or the cassettes shown in the above described mode are arbitrary while the utilized materials and the process steps in the process methods and the manufacturing methods are also arbitrary.

Although the present invention has been fully described by way of examples with reference to the accompanying drawings, it is to be noted that various changes and modifications will be apparent to those skilled in the art. Therefore, unless otherwise such changes and modifications depart from the scope of the present invention, they should be construed as being included therein.

What is claimed is:

1. A processing method of a plurality of film comprising the steps of:
(a) holding a periphery of each of the films by a film holder;
(b) executing a first process on the films after the step (a); and
(c) executing a second process on the films after the step (b), the second process being different from the first process.

2. A processing method as claimed in claim 1, wherein the films are sequentially processed in at least one of the first and second processes.

3. A processing method as claimed in claim 2, wherein the at least one of the first and second processes in which the films are to be sequentially processed includes at least one of processes of a film washing, a drying, a resist application, an exposure to light, a resist development, an electrode film etching, a resist exfoliation, an insulating film application, an insulating film burning, an orientation film application, an orientation film burning, a spacer dispersion, a seal printing and a resin structure printing.

4. A processing method as claimed in claim 1, wherein the films are simultaneously processed in at least one of the first and second processes.

5. A processing method as claimed in claim 4, further comprising a step of:
(d) holding the film holder in a magazine cassette before the at least one of the first and second processes in which the films are to be simultaneously processed.

6. A processing method as claimed in claim 4, wherein the at least one of the first and second processes in which the films are to be simultaneously processed includes at least one of processes of a washing, a drying, a resist pre-baking, a resist development, an electrode film etching, a resist exfoliation, an insulating film burning, an orientation film burning, a spacer heat processing, a seal burning and a resin structure burning.

7. A processing method as claimed in claim 1, wherein the films are substrates for at least one liquid crystal display element.

8. A processing method as claimed in claim 1, wherein each of the film holders has a shape capable of exposing a major portion of a surface of the film.

9. A processing method as claimed in claim 8, wherein each of the film holders has a frame shape and holds a periphery of the film.

10. A processing method as claimed in claim 9, wherein each of the film holders has a holding mechanism for holding the periphery of the film.

11. A processing method as claimed in claim 10, wherein the holding mechanism is selected from a clip, a magnet, and a binder.

12. A processing method of a plurality of film comprising the steps of:
(a) holding a periphery of each of the films by a film holders, respectively;
(b) carrying out, after the step (a), a sequential process on the films held by the film holders; and
(c) carrying out, after the step (c), a batch process on the films held by the film holders that have been installed in a magazine cassette, wherein the steps (b) and (c) are carried out in any order.

13. A processing method as claimed in claim 12, wherein the step (c) is carried out prior to the step (b).

14. A processing method as claimed in claim 13, further comprising:
(d) setting, after the step (a) and before the step (c), the film holders in the magazine cassette; and
(e) drawing, after the step (c) and before the step (b), the film holders from the magazine cassette.

15. A processing method as claimed in claim 12, wherein the step (b) is carried out prior to the step (c).

16. A processing method as claimed in claim 15, further comprising:
(d) setting, after the step (b) and before the step (c), the film holders to the magazine cassette.

17. A processing method as claimed in claim 12, wherein the sequential process includes at least one of processes of a film washing, a drying, a resist application, an exposure to light, a resist development, an electrode film etching, a resist exfoliation, an insulating film application, an insulating film burning, an orientation film application, an orientation film burning, a spacer dispersion, a seal printing and a resin structure printing.

18. A processing method as claimed in claim 12, wherein the batch process includes at least one of processes of a washing, a drying, a resist pre-baking, a resist development, an electrode film etching, a resist exfoliation, an insulating film burning, an orientation film burning, a spacer heat processing, a seal burning and a resin structure burning.

19. A processing method as claimed in claim 12, wherein the films are substrates for at least one liquid crystal display element.

20. A processing method as claimed in claim 12, wherein each of the film holders has a shape capable of exposing a major portion of a surface of the film.

21. A processing method as claimed in claim 20, wherein each of the film holders has a frame shape and holds a periphery of the film.

22. A processing method as claimed in claim 20, wherein each of the film holders has a holding mechanism for holding the periphery of the film.

23. A processing method as claimed in claim 22, wherein the holding mechanism is selected from a clip, a magnet, and a binder.
